(19) United States
(12) Patent Application Publication
(10) Pub. No.: US 2013/0027877 A1
(43) Pub. Date: Jan. 31, 2013

(54) ELECTRONIC DEVICE

(71) Applicants: Ching-Fu Yang, Taipei City (TW); Hui-Lian Chang, Taipei City (TW); Ming-Wang Lin, Taipei City (TW); Chun-Wei Chang, Taipei City (TW)

(72) Inventors: Ching-Fu Yang, Taipei City (TW); Hui-Lian Chang, Taipei City (TW); Ming-Wang Lin, Taipei City (TW); Chun-Wei Chang, Taipei City (TW)

(73) Assignee: COMPAL ELECTRONICS, INC., Taipei City (TW)

(21) Appl. No.: 13/553,831

(22) Filed: Jul. 20, 2012

Related U.S. Application Data
(60) Provisional application No. 61/511,978, filed on Jul. 26, 2011.

(51) Int. Cl. H05K 7/20

(52) U.S. Cl. 361/692; 361/690; 361/695

(57) ABSTRACT

An electronic device including a main body, a rotating base, a motherboard and a driving module is provided. The rotating base has a first vent. The rotating base is pivoted to the main body and suitable for being rotated between an operating position and a retracting position. When the rotating base is located at the operating position, the first vent is exposed from the main body, and when the rotating base is located at the retracting position, the first vent is retracted in the main body. The driving module includes a controlling element and a first locking element. The controlling element is disposed on the main body and suitable for moving between an enable position and a disable position. The first locking element is connected to the controlling element, and the controlling element drives the first locking element to position the rotating base.

### CROSS-REFERENCE TO RELATED APPLICATION

This application claims the priority benefits of U.S. provisional application Ser. No. 61/511,978, filed on Jul. 26, 2011. The entirety of the above-mentioned patent application is hereby incorporated by reference herein and made a part of this specification.

### BACKGROUND OF THE INVENTION

1. Field of the Invention

The present invention is related to an electronic device and more particularly, to an electronic device capable of retracting a vent.

2. Description of Related Art

In recent years, with the development of the technical industry, products of electronic devices, such as notebooks (NBs), personal digital assistants (PDAs) and smart phones have frequently appeared in the daily lives. The electronic devices become more and more type and functional diversities as well as more popularized for providing the convenience and practicability so as to be used for various purposes.

However, nowadays, the design of the electronic devices is required to meet lightness, slimness and size-compactness, which results in difficulties to increase heat sinking elements or to enlarge heat sinking spaces in limited casing spaces. Accordingly, how to improve the heat sinking effect of the electronic devices is an important issue that the current design of the electronic devices has to deal with.

### SUMMARY OF THE INVENTION

The present invention is related to an electronic device having a vent capable of being retracted inside the electronic device.

The present invention is directed to electronic device including a main body, a rotating base and a driving module. The rotating base has a first vent. The rotating base is pivoted to the main body and suitable for being rotated in relative to the main body between an operating position and a retracting position. When the rotating base is located at the operating position, the first vent is exposed from the main body, and when the rotating base is located at the retracting position, the first vent is retracted in the main body. The driving module has a controlling element and a first locking element. The controlling element is disposed on the main body and suitable for moving in relative to the main body between an enable position and a disable position. The first locking element is connected to the controlling element, and the controlling element drives the first locking element to position the rotating base.

In an embodiment of the present invention, the electronic device further includes a fan disposed on the rotating base and adjacently to first vent.

In an embodiment of the present invention, the main body has a second vent. When the rotating base is located at the retracting position, the first vent is located at one side of the second vent.

In an embodiment of the present invention, the electronic device further includes an elastic element disposed on the main body. When the controlling element is located at the disable position, the rotating base is locked at the retracting position by the first locking element. When the controlling element is located at the enable position, the rotating base is released by the first locking element and rotated to the operating position by elasticity of the elastic element.

In an embodiment of the present invention, the electronic device further includes a motherboard disposed in the rotating base.

In an embodiment of the present invention, the electronic device further includes a connection port disposed on the rotating base and adjacently to the first vent.

In an embodiment of the present invention, the main body is suitable for being placed on a plane. When the rotating base is located at the operating position, the main body is propped up from the plane by the rotating base.

In an embodiment of the present invention, the main body has a top surface and a bottom surface opposite to each other. The controlling element is disposed on the top surface, and the rotating base is pivoted to the bottom surface.

In an embodiment of the present invention, when the controlling element is pushed along a first direction, the first locking element is departed from the rotating base along the first direction.

In an embodiment of the present invention, the driving module further includes at least one second locking element connected to the first locking element. When the controlling element is located at the disable position, the rotating base is locked at the retracting position by the second locking element. When the first locking element is departed from the rotating base along the first direction, the first locking element drives the second locking element to depart from the rotating base along a second direction.

In an embodiment of the present invention, the second direction is perpendicular to the first direction.

In an embodiment of the present invention, the first locking element has a protrusion portion, and the rotating base has a slot. The protrusion portion is suitable for being wedged to the slot.

In an embodiment of the present invention, the electronic device further includes a first magnetic element and a second magnetic element. The first magnetic element is disposed on the controlling element, and the second magnetic element is disposed on the rotating base. When the controlling element is located at the disable position, the first magnetic element and the second magnetic element are dislocated from each other. When the controlling element is located at the enable position, the first magnetic element is aligned to the second magnetic element, and the rotating base is rotated to the operating position by magnetic repulsion between the first magnetic element and the second magnetic element.

In an embodiment of the present invention, the electronic device further includes a first electromagnet component and a second electromagnet component. The first electromagnet component is disposed on the main body, and the second electromagnet component is disposed on the rotating base. The rotating base is suitable for being rotated to the operating position by magnetic repulsion between the first electromagnet component and the second electromagnet component.

To sum up, the present invention is directed to an electronic device having a first vent disposed on a rotating base so that a user can push a controlling element to drive a rotating base to rotate in relative to a main body between an operating position and a retracting position. When the rotating base is located at the operating position, the first vent is exposed from the electronic device, and airflow can be blown by the fan to flow out of the electronic device through the first vent. Accordingly, the first vent exposed from the main body facilitates the thermal efficiency of the electronic device.

In order to make the aforementioned and other features and advantages of the invention more comprehensible, embodiments accompanying figures are described in detail below.

### BRIEF DESCRIPTION OF THE DRAWINGS

The accompanying drawings are included to provide a further understanding of the present invention, and are incorporated in and constitute a part of this specification. The drawings illustrate embodiments of the present invention and, together with the description, serve to explain the principles of the present invention.

FIG. 1 is a three-dimensional diagram illustrating an electronic device according to an embodiment of the present invention.

FIG. 2A is a side view illustrating the electronic device depicted in FIG. 1.

FIG. 2B is a schematic diagram illustrating a rotating base depicted in FIG. 2A being rotated in relative to a main body.

FIG. 3A is a partial three-dimensional diagram illustrating the electronic device depicted in FIG. 2A.

FIG. 3B is partial three-dimensional diagram illustrating the electronic device depicted in FIG. 2B.

FIG. 4A is an enlarged view illustrating a controlling element of the electronic device depicted in FIG. 1.

FIG. 4B is a schematic diagram illustrating the controlling element of FIG. 4A being pushed.

FIG. 5A is a side view illustrating the electronic device depicted in FIG. 1.

FIG. 5B is a side view illustrating the rotating base depicted in FIG. 5A being rotated in relative to the main body.

FIG. 6A is a top view illustrating a portion of elements of the electronic device depicted in FIG. 3A.

FIG. 6B is a top view illustrating a portion of the elements of the electronic device depicted in FIG. 3B.

FIG. 7A is an enlarged view illustrating an area A of the electronic device depicted in FIG. 3A.

FIG. 7B is an enlarged view illustrating an area A′ of the electronic device depicted in FIG. 3B.

FIG. 8A is an enlarged view illustrating an area B of the electronic device depicted in FIG. 3A.

FIG. 8B is an enlarged view illustrating the area B′ of the electronic device depicted in FIG. 3B.

FIG. 9A is an enlarged view illustrating the area C of the electronic device depicted in FIG. 3A.

FIG. 9B is an enlarged view illustrating the area C′ of the electronic device depicted in FIG. 3B.

FIG. 10A is a partial schematic view illustrating the electronic device depicted in FIG. 1.

FIG. 10B is a schematic view illustrating the rotating base depicted in FIG. 10A being rotated in relative to the main body.

FIG. 11A a partial schematic illustrative an electronic device according to another embodiment of the present invention.

FIG. 11B is a schematic view illustrating the rotating base depicted in FIG. 11A being rotated in relative to the main body.

### DESCRIPTION OF EMBODIMENTS

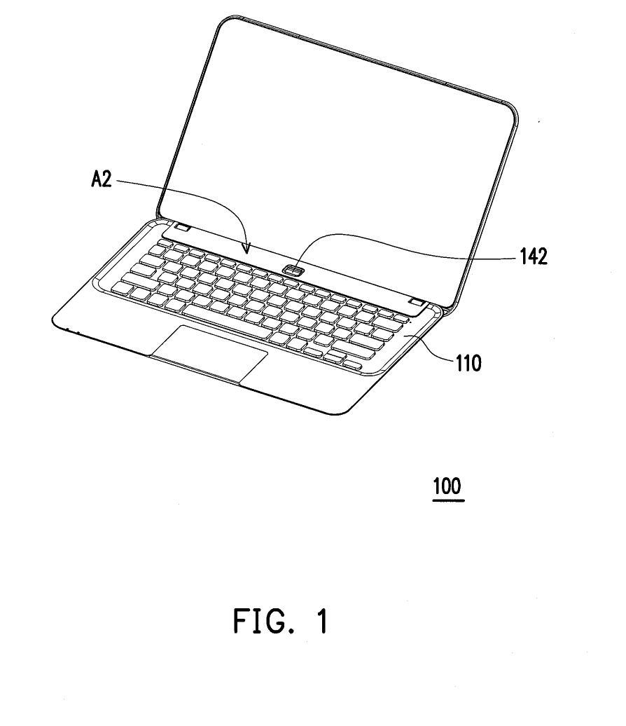

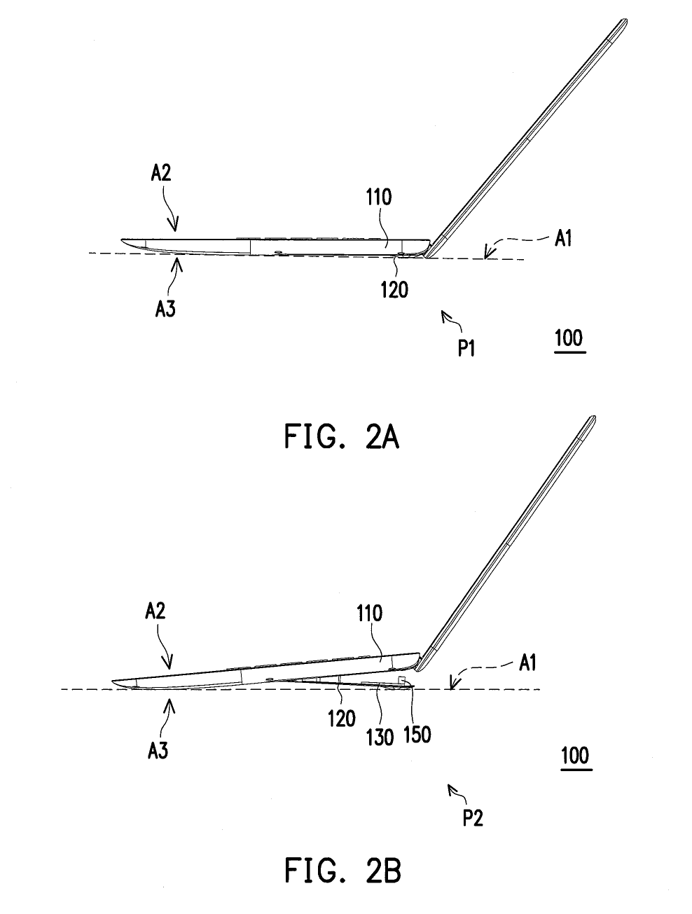

FIG. 1 is a three-dimensional diagram illustrating an electronic device according to an embodiment of the present invention. FIG. 2A is a side view illustrating the electronic device depicted in FIG. 1. FIG. 2B is a schematic diagram illustrating a rotating base depicted in FIG. 2A being rotated in relative to a main body. Referring to FIG. 1, FIG. 2A and FIG. 2B, in the present embodiment, an electronic device 100 is, for example, a notebook (NB). In other embodiments, the electronic device 100 may be any other type of electronic device, such as a tablet computer or an ultra-thin computer, and the present invention is not limited thereto. The electronic device 100 includes a main body 110, a rotating base 120, a motherboard 130 and a connection port 150. The rotating base 120 is pivoted to the main body 110, and the rotating base 120 is suitable for being rotated in relative to the main body 110 between a retracting position P1 (as shown in FIG. 2A) and an operating position P2 (as shown in FIG. 2B).

The motherboard 130 is disposed in the rotating base 120, and the connection port 150 is disposed on the motherboard 130. When the rotating base 120 is located at the retracting position P1, the motherboard 130 and the connection port 150 are hidden in the main body 110, as shown in FIG. 2A. When the rotating base 120 is located at the operating position P2, the connection port 150 on the motherboard is exposed from the main body 110, as shown in FIG. 2B. When a user is about to use the connection port 150, the rotating base 120 is rotated in relative to the main body 110 to the operating position P2 to expose the connection port 150. At this time, the user could connect an external device to the connection port 150 so that a signal is transmitted between the external device and the motherboard 130. When the user does not want to use the connection port 150, the rotating base 120 could be rotated in relative to the main body 110 to the retracting position P1 so that the motherboard 130 and the connection port 150 are hidden inside the main body 110 to protect the motherboard 130 and the connection port 150 from dust.

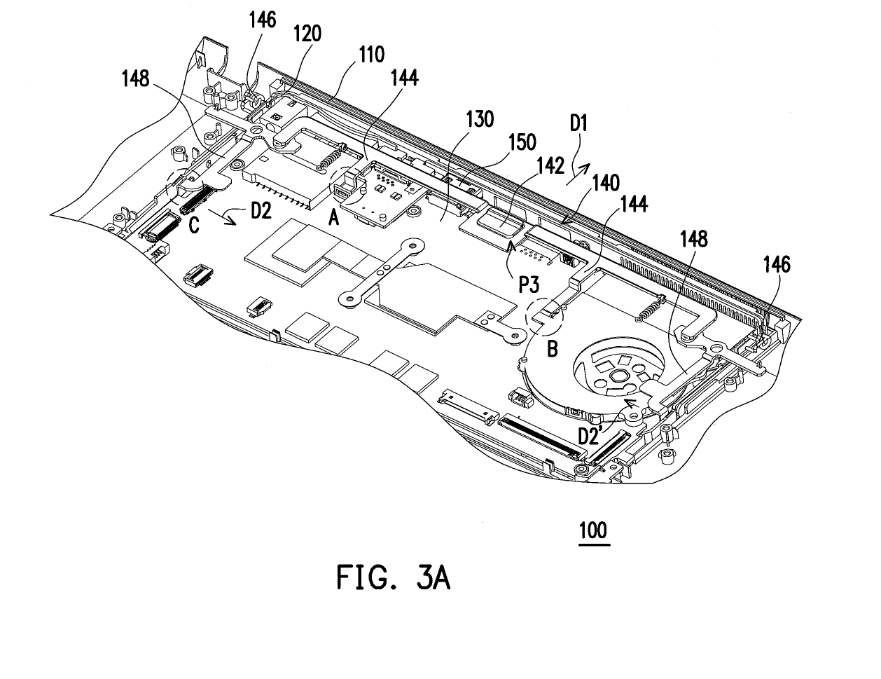

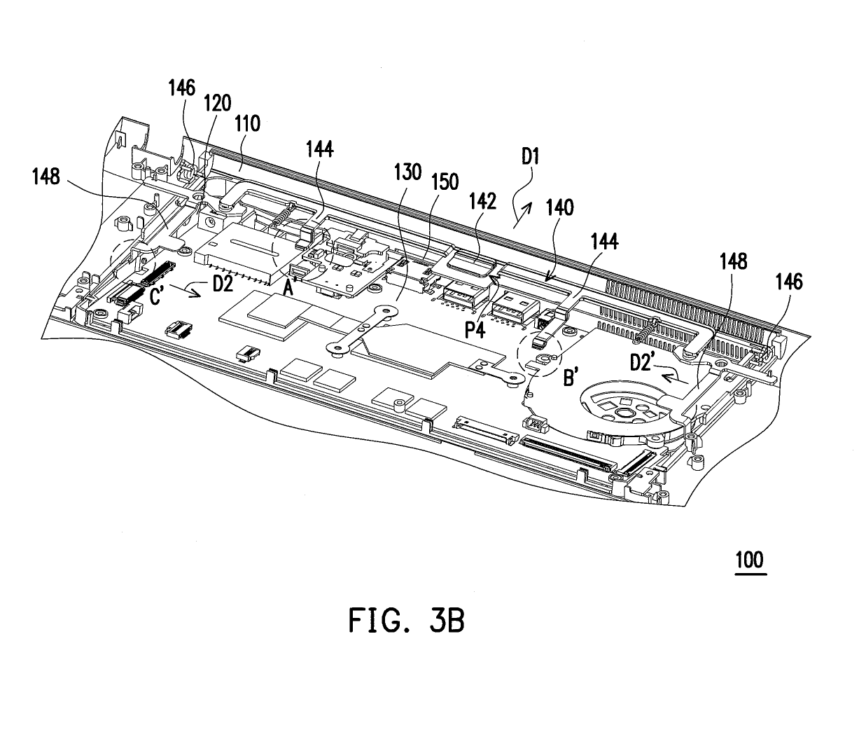

However, in other embodiments, the motherboard may be disposed on the main body, and the connection port may be disposed on the rotating base and adjacently to a first vent (depicted in FIG. 3A and FIG. 3B). At this time, the electronic device further includes a circuit board (not shown) disposed on the rotating base. The connection port is electrically connected to the circuit board, and the circuit board is electrically connected to the motherboard on the main body through a flexible circuit board (not shown). Accordingly, the user may also connect the external device to the connection port so that the signal is transmitted between the external device and the motherboard 130.

Additionally, as shown in FIG. 2A, the main body 110 is suitable for being placed on a plane A1 for the user's operation. The plane A1 may be, for example, a tabletop or any other plane for placing the main body 110. When the rotating base 120 is rotated from the retracting position P1 depicted in FIG. 2A to the operating position P2 depicted in FIG. 2, the main body 110 is propped up from the plane A1 by the rotating base 120, so that the electronic device 100 has a good angle for usage.

Referring to FIG. 3A and FIG. 3B, in the present embodiment, the electronic device 100 further includes a driving module 140. The driving module 140 includes a controlling element 142, first locking elements 144 (shown as two) and elastic elements 146 (shown as two). The controlling element 142 is exposed from a top surface of the main body 110, and the first locking elements 144 and the elastic elements 146 are disposed inside the main body 110. The first locking elements 144 are connected with the controlling element 142. The elastic elements 146 are disposed in the main body 110. The rotating base 120 is rotated in relative to the main body 110 together with the operation of the driving module 140, which will be described in detail hereinafter.

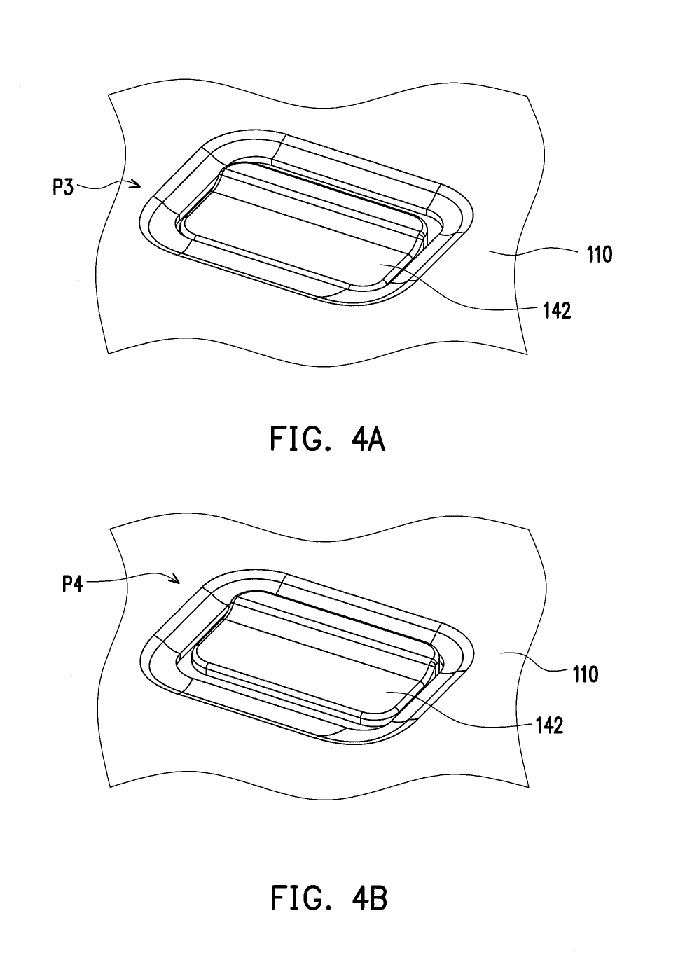

Referring to FIG. 4A and FIG. 4B, the controlling element 142 is suitable for moving in relative to the main body 110 between a disable position P3 (as shown in FIG. 3A and FIG. 4A) and an enable position P4 (as shown in FIG. 3B and FIG. 4B). In present embodiment, by the user pushing the controlling element 142, the controlling element 142 moves horizontally in relative to the main body 110 between the disable position P3 and the enable position P4, but the present invention is not limited thereto. The controlling element may move perpendicularly in relative to the main body 110 so as to be driven to move by the user's pressing.

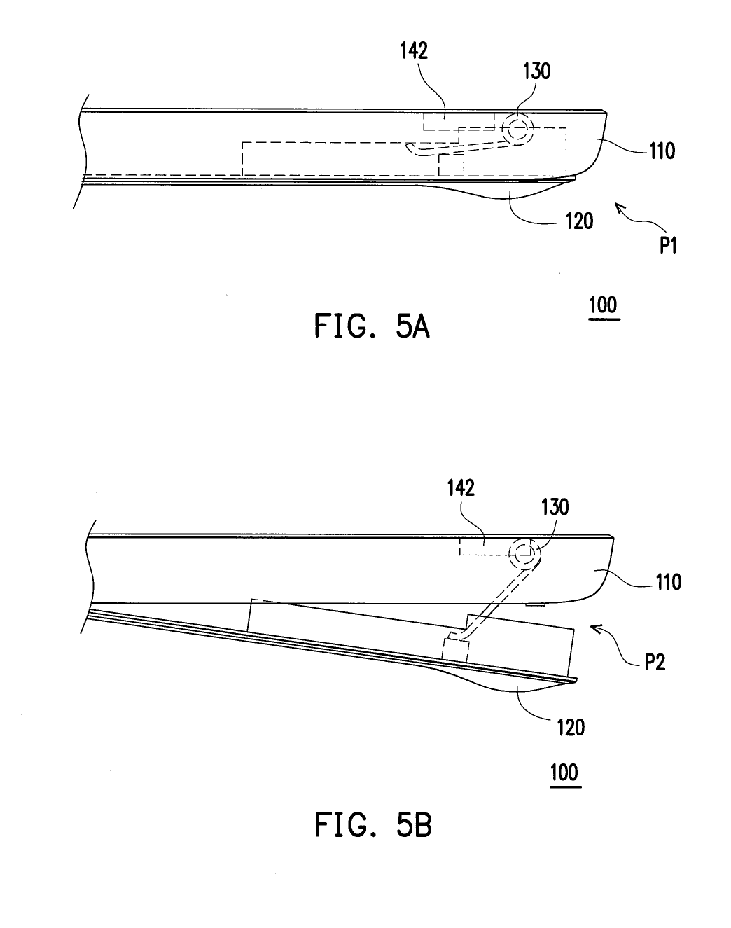

When the controlling element 142 is located at the disable position P3, the rotating base 120 is locked by the first locking element 144 at the retracting position P1 shown in FIG. 2A. At this time, the elastic element 146 disposed on the main body 110 is pressed by the rotating base 120 so as to store elastic potential, as shown in FIG. 5A. When the controlling element 142 is located at the enable position P4, the rotating base 120 is released by the first locking element 144. At this time, the elastic element 146 provide elasticity by releasing the elastic potential so that the rotating base 120 is rotated by the elasticity to the operating position P2 depicted in FIG. 2B, as shown in FIG. 5B. It should be noted that with the elasticity provided by the elastic element 146, the rotating base 120 is not only rotated to the operating position P2, but also used as support to prop up the main body 110 from the plane so that the electronic device 100 is provided with has a good angle for usage.

Referring to FIG. 3A and FIG. 3B, in the present embodiment, the electronic device 100 has a fan 132. The fan 132 is disposed on the motherboard 130 in the rotating base 120 and electrically connected to the motherboard 130. The rotating base 120 has a first vent 124, and the main body 110 has a second vent 112. The fan 132 is disposed adjacently to the first vent 124.

In the present embodiment, the fan 132 is a blowing fan, while in other embodiments, the fan 132 may be a suction fan, and the present invention is not limited thereto. When electronic device 100 is operated, airflow may be blown from the fan 132 and blown out of the electronic device 100 through the first vent 124 and the second vent 112 for dissipating heat from the electronic device 100.

In particular, when the rotating base 120 is located at the retracting position P1, the first vent 124 is retracted in the main body 110. The first vent 124 is located at one side of the second vent 112 and adjacent thereto. Thus, the airflow blown from the fan 132 is flowed out of the rotating base 120 through the first vent 124 first and then, out of the main body 110 through the second vent 112 so that the electronic device 100 has heat-dissipation function, as shown in FIG. 3A. Therefore, the rotating base 120 does not bring bad influence on the thermal efficiency of the main body 110 even though it is retracted in the main body 110.

In the opposite, when the rotating base 120 is located at the operating position P2, the first vent 124 is exposed from the main body 110 with the rotation of the rotating base 120 so that the first vent 124 and the second vent 112 is aligned perpendicularly. Thus, the airflow blown from the fan 132 is flowed out of the electronic device 100 through both the first vent 124 and the second vent 112, respectively, as shown in FIG. 3B. Thus, when the rotating base 120 is located at the operating position P2, the ventilation area of the electronic device 100 is increased so as to improve the thermal efficiency of the electronic device 100.

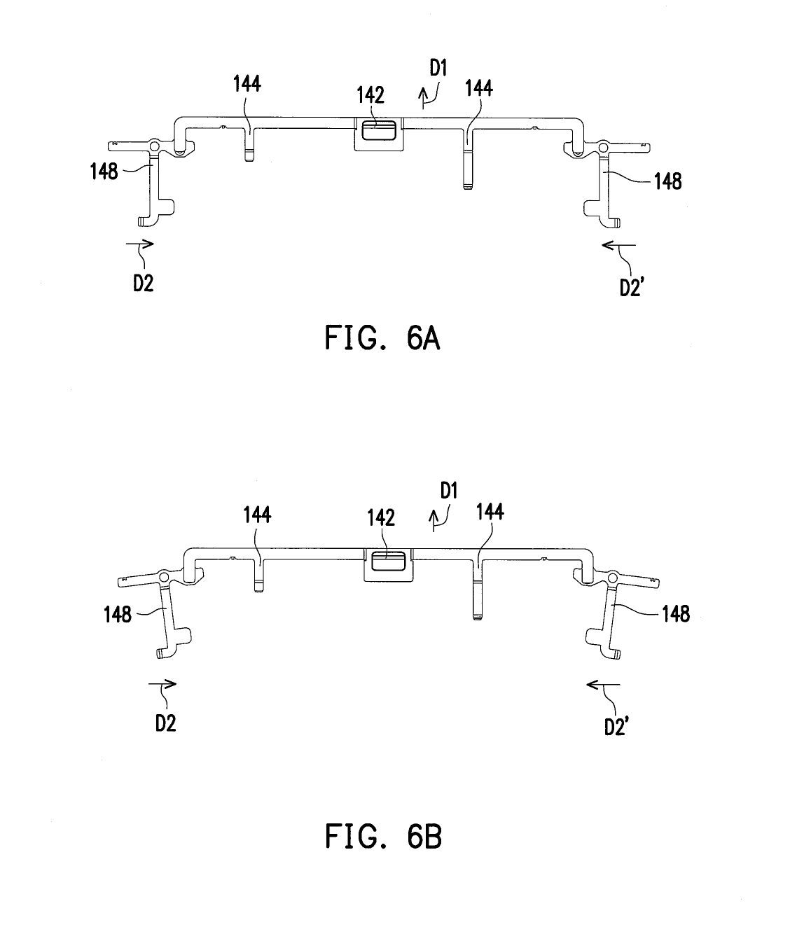

Referring to FIG. 3A, FIG. 3B, FIG. 6A and FIG. 6B, in the present embodiment, the driving module 140 further includes second locking elements 148 (shown as two) connected to the two first locking elements 144, respectively. When the controlling element 142 is located at the disable position P3, the rotating base 120 is locked at the retracting position P1 depicted in FIG. 2A by the second locking elements 148. When the user pushes the controlling element 142 along a first direction D1 to drive the controlling element 142 to move from the disable position P3 to the enable position P4, the first locking element 144 is driven by the controlling element 142 to move from the position depicted in FIG. 3A to the position depicted in FIG. 3B, so that the first locking element 144 is departed from the rotating base 120 along the first direction D1. And, the second locking elements 148 are driven by the first locking element 144 to move from the position depicted in FIG. 3A to the position depicted in FIG. 3B, so that the second locking elements 148 are departed from the rotating base 120 along a second direction D2 (or D2′). In the meantime, the rotating base 120 is pushed by the elastic element 146 to the operating position P2 depicted in FIG. 2B.

In the present embodiment, the second locking elements 148 are, for example, pivoted to the main body 110 and operated in a rotation manner. The second direction D2 is perpendicular to the first direction D1, while in other embodiments, the second locking elements 148 are connected to the main body 110 in other manners, and the second direction D2 may not be perpendicular to the first direction D1, which the present invention is not limited thereto.

Hereinafter, how the rotating base 120 is locked by the first locking elements 144 and the second locking elements 148 will be described in detail with reference to the drawings.

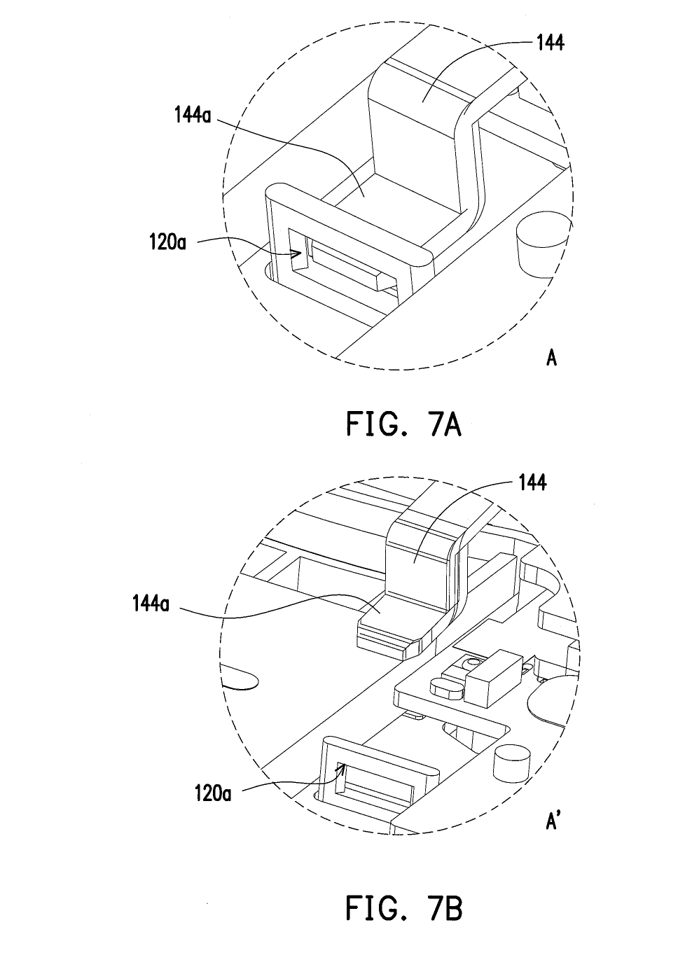

FIG. 7A is an enlarged view illustrating an area A of the electronic device depicted in FIG. 3A. FIG. 7B is an enlarged view illustrating an area A′ of the electronic device depicted in FIG. 3B. Referring to FIG. 7A and FIG. 78, the first locking element 144 in the area A has a protrusion portion 144a, and the rotating base 120 has a slot 120a. The protrusion portion 144a, as shown in FIG. 7A, is suitable for being wedged to the slot 120a so that the first locking element 144 is locked on the rotating base 120. The protrusion portion 144a is suitable for, as shown in FIG. 7B, being departed from the slot 120a, so that rotating base 120 is released by the first locking element 144.

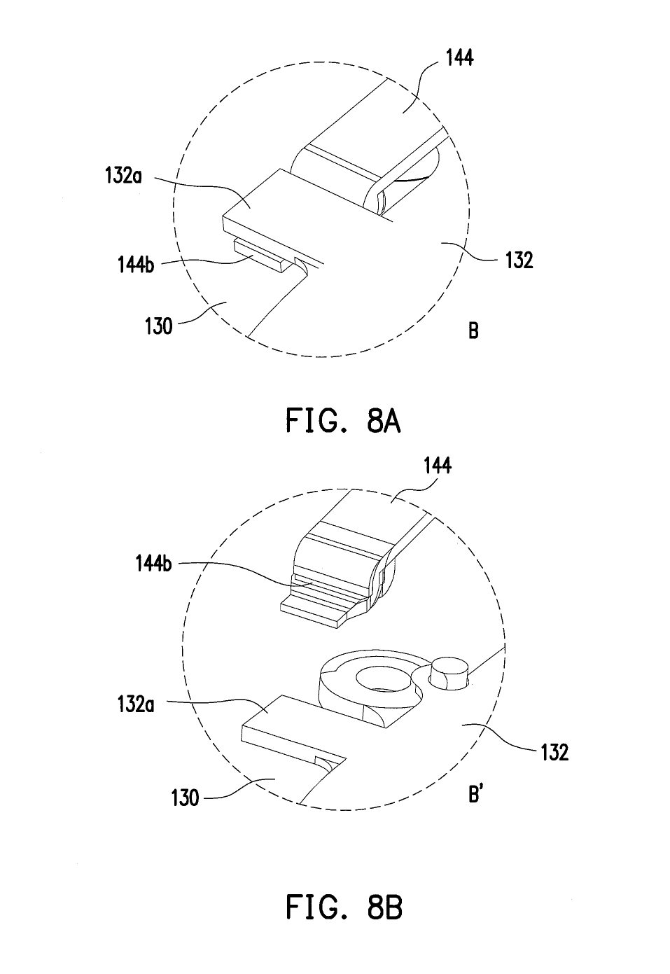

FIG. 8A is an enlarged view illustrating an area B of the electronic device depicted in FIG. 3A. FIG. 8B is an enlarged view illustrating an area B′ of the electronic device depicted in FIG. 3B. Referring to FIG. 8A and FIG. 8B, the first locking element 144 in the area B also has a protrusion portion 144b, and the first locking element 144 is locked by a method different from that to lock the first locking element 144a in the area A. The protrusion portion 144b of the first locking element 144 is, for example, is locked by a stopping element 132a extended from the fan 132 so that the first locking element 144 is locked on the rotating base 120, as shown in FIG. 8A, and the protrusion portion 144b is suitable for being departed from the stopping element 132a, as shown in FIG. 8B, so that the rotating base 120 is released by the first locking element 144.

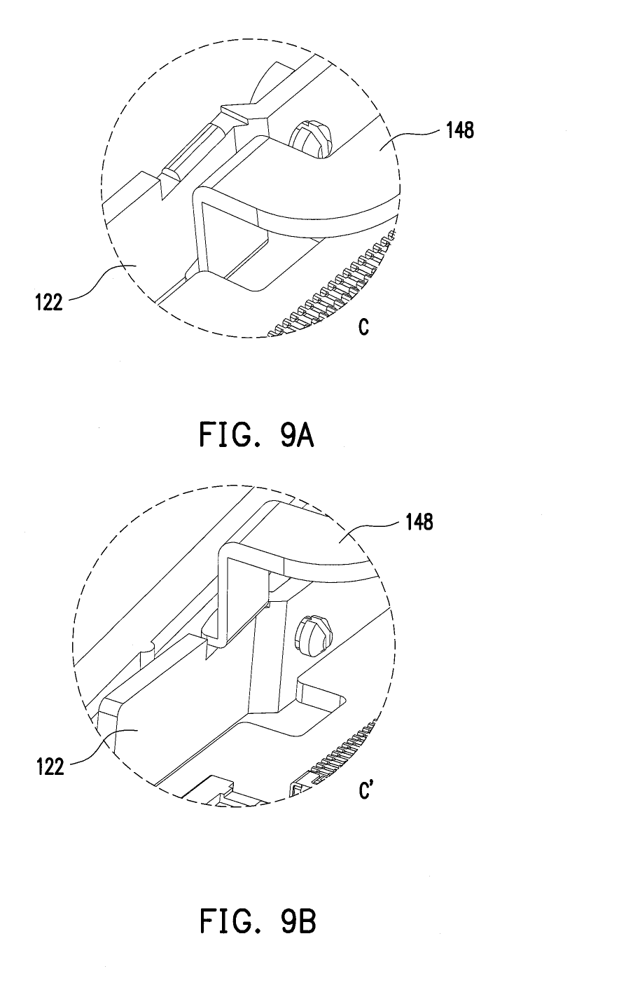

FIG. 9A is an enlarged view illustrating an area C of the electronic device depicted in FIG. 3A. FIG. 9B is an enlarged view illustrating an area C′ of the electronic device depicted in FIG. 3B. Referring to FIG. 9A and FIG. 9B, the second locking element 148 in the area C has a protrusion portion 148a. The protrusion portion 148a of the second locking element 148 is, for example, locked on a side wall 122 of the rotating base 120, as shown in FIG. 9A, so that the second locking element 148 is locked on the rotating base 120, and the protrusion portion 148a is suitable for being departed from the side wall 122, as shown in FIG. 9B, so that the rotating base 120 is released by the second locking element 148.

In other embodiments, the rotating base 120 may by locked by the first locking element 144 and the second locking element 148 using any other suitable structure, and the invention is not limited thereto.

Referring to FIG. 1, FIG. 2A and FIG. 2B, in the present embodiment, the main body 110 has a top surface A2 and a bottom surface A3 opposite to each other. The controlling element 142 is disposed on the top surface A2 of the main body 110, and the rotating base 120 is pivoted to the bottom surface A3 of the main body 110. Thus, the user can conveniently push the controlling element 142 on the top surface A2 to drive the rotating base 120 to rotate in relative to the main body 110. In other embodiments, the opposite positions of the controlling element 142 and the rotating base 120 may be configured in other suitable manners, and the present invention is not limited thereto.

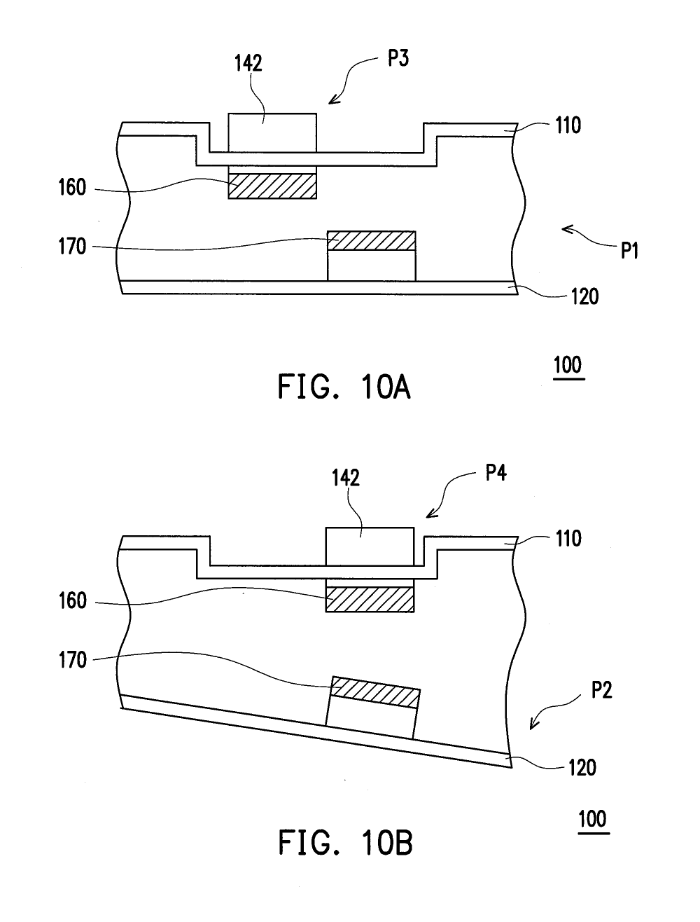

Referring to FIG. 10A and FIG. 10B, the electronic device 100 further includes a first magnetic element 160 and a second magnetic element 170. Both the first magnetic element 160 and the second magnetic element 170 are, for example, permanent magnets. The first magnetic element 160 is disposed on bottom of the controlling element 142, and the second magnetic element 170 is disposed on the rotating base 120. When the controlling element 142 is located at the disable position P3, the first magnetic element 160 and the second magnetic element 170 are dislocated from each other, as shown in FIG. 10A. When the controlling element 142 is pushed to the enable position P4, the first magnetic element 160 is aligned to the second magnetic element 170, as shown in FIG. 10B. At this time, the rotating base 120 is driven to rotate to the operating position P2 by magnetic repulsion between the first magnetic element 160 and the second magnetic element 170. With the disposition of the first magnetic element 160 and the second magnetic element 170, the rotating base 120 is not only rotated by the elasticity of the elastic element 146 depicted in FIG. 5A and FIG. 5B but also rotated by magnetism provided by first magnetic element 160 and the second magnetic element 170 so that the operation of the rotating base 120 can be more smooth. In addition, when the rotating base 120 is located at the operating position P2 to prop up the main body 110, the magnetic repulsion between the first magnetic element 160 and the second magnetic element 170 is capable of supporting the weight of the main body 110.

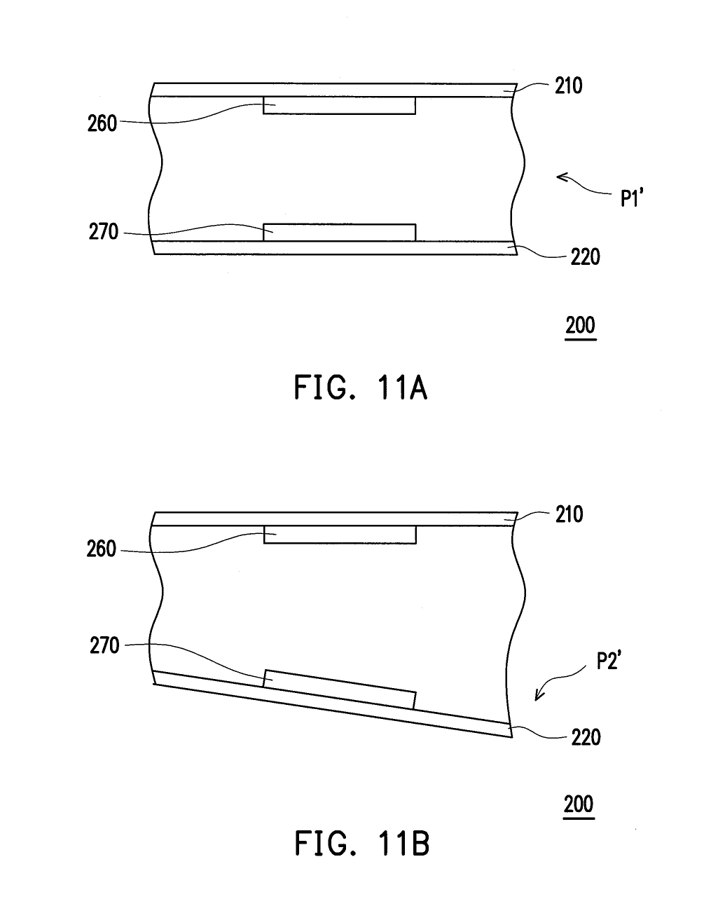

Referring to FIG. 11A and FIG. 11B, an electronic device 200 of the present embodiment is disposed similarly to the electronic device 100 depicted in FIG. 10A and FIG. 10B. The difference between the electronic device 200 and the electronic device 100 is that the electronic device 200 uses a first electromagnet component 260 and a second electromagnet component 270 in replacement with the functions of the first magnetic element 160 and the second magnetic element 170. In detail, the first electromagnet component 260 is disposed on a main body 210, and the second electromagnet component 270 is disposed on a rotating base 220. When the first electromagnet component 260 and the second electromagnet component 270 are powered on to generate magnetism, the rotating base 220 is suitable for being rotated from a retracting position P1′ depicted in FIG. 11A to an operating position P2′ depicted in FIG. 11B by magnetic repulsion between the first electromagnet component 260 and the second electromagnet component 270. With the disposition of the first electromagnet component 260 and the second electromagnet component 270, the rotating base 220 is not only rotated by the elasticity of the elastic element, but also rotated by the magnetism provided by the first electromagnet component 260 and the second electromagnet component 270 so that the operation of the rotating base 220 can be more smooth. Furthermore, when the rotating base 220 is located at the operating position P2 to prop up the main body 210, the magnetic repulsion between the first electromagnet component 260 and the second electromagnet component 270 is capable of supporting the weight of the main body 210.

Based on the foregoing, the present invention is directed to an electronic device having a first vent disposed on a rotating base, and the user can push a controlling element to drive the rotating base to rotate in relative to a main body between an operating position and a retracting position. When the rotating base is located at the operating position, a first vent is exposed from the electronic device, such that airflow is blown by the fan and flowed out of the electronic device through the first vent. Accordingly, the first vent can facilitate the thermal efficiency of the electronic device by being exposed from the main body.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. An electronic device, comprising:
a main body;
a rotating base, having a first vent, pivoted to the main body and suitable for being rotated in relative to the main body between an operating position and a retracting position, wherein when the rotating base is located at the operating position, the first vent is exposed from the main body, and when the rotating base is located at the retracting position, the first vent is retracted in the main body; and
a driving module, comprising:
a controlling element, disposed on the main body and suitable for moving in relative to the main body between an enable position and a disable position; and
a first locking element, connected to the controlling element, wherein the controlling element drives the first locking element to position the rotating base.

2. The electronic device according to claim 1, further comprising a fan disposed on the rotating base and adjacently to the first vent.

3. The electronic device according to claim 1, wherein the main body has a second vent, and when the rotating base is located at the retracting position, the first vent is located at one side of the second vent.

4. The electronic device according to claim 1, further comprising an elastic element disposed on the main body, wherein when the controlling element is located at the disable position, the rotating base is locked at the retracting position by the first locking element, and when the controlling element is located at the enable position, the rotating base is released by the first locking element and rotated to the operating position by elasticity of the elastic element.

5. The electronic device according to claim 1, further comprising a motherboard disposed in the rotating base.

6. The electronic device according to claim 1, further comprising a connection port disposed on the rotating base and adjacently to the first vent.

7. The electronic device according to claim 1, wherein the main body is suitable for being placed on a plane, and when the rotating base is located at the operating position, the main body is propped up from the plane by the rotating base.

8. The electronic device according to claim 1, wherein the main body has a top surface and a bottom surface opposite to each other, the controlling element is disposed on the top surface, and the rotating base is pivoted to the bottom surface.

9. The electronic device according to claim 1, wherein when the controlling element is pushed along a first direction, the first locking element is departed from the rotating base along the first direction.

10. The electronic device according to claim 6, wherein the driving module further comprises a second locking element connected to the first locking element, when the controlling element is located at the disable position, the rotating base is locked at the retracting position by the second locking element, and when the first locking element is departed from the rotating base along the first direction, the first locking element drives the second locking element to depart from the rotating base along a second direction.

11. The electronic device according to claim 7, wherein the second direction is perpendicular to the first direction.

12. The electronic device according to claim 1, wherein the first locking element has a protrusion portion, the rotating base has a slot, and the protrusion portion is suitable for being wedged to the slot.

13. The electronic device according to claim 1, further comprising a first magnetic element and a second magnetic element, wherein the first magnetic element is disposed on the controlling element, the second magnetic element is disposed on the rotating base, when the controlling element is located at the disable position, the first magnetic element and the second magnetic element are dislocated from each other, and when the controlling element is located at the enable position, the first magnetic element is aligned to the second magnetic element, and the rotating base is rotated to the operating position by magnetic repulsion between the first magnetic element and the second magnetic element.

14. The electronic device according to claim 1, further comprising a first electromagnet component and a second electromagnet component, wherein the first electromagnet component is disposed on the main body, the second electromagnet component is disposed on the rotating base, and the rotating base is suitable for being rotated to the operating position by magnetic repulsion between the first electromagnet component and the second electromagnet component.
